(19) United States
(12) Patent Application Publication
(10) Pub. No.: US 2015/0226788 A1
(43) Pub. Date: Aug. 13, 2015

(54) OPTICAL DEVICE FAILURE DETECTION

(71) Applicant: FUJITSU LIMITED, Kawasaki-shi (JP)

(72) Inventor: Asako TODA, Santa Clara, CA (US)

(73) Assignee: FUJITSU LIMITED, Kawasaki-shi (JP)

(21) Appl. No.: 14/175,900

(22) Filed: Feb. 7, 2014

(51) Int. Cl. G01R 31/26

(52) U.S. Cl. CPC G01R 31/2635

(57) ABSTRACT

An optical device monitoring system may include a detection unit and a decision unit. The detection unit may be configured to detect a current through an optical device or to detect a voltage across the optical device. The decision unit may be configured to receive the detected current or the detected voltage and to compare the detected current or the detected voltage with normal operating electrical characteristics of the optical device. The decision unit may be further configured to determine optical function failure of the optical device based on the comparison between the detected current or the detected voltage and the normal operating electrical characteristics of the optical device.

### FIELD

The embodiments discussed herein are related to optical device failure detection.

### BACKGROUND

Computing and networking technology have transformed our world. As the amount of information communicated over networks has increased, high speed transmission has become ever more important. Many high speed data transmission optical networks rely on optical transceivers for facilitating transmission and reception of digital data embodied in the form of optical signals over optical fibers.

Optical transceivers may include optical devices, such as photodiodes and optical modulators, implemented on silicon dies. Optical devices implemented on silicon dies, in some circumstances, may have low reliability and low yield. To help to reduce failures in optical networks, optical devices may be tested before being implemented in optical networks. The optical devices may also be tested after being implemented in the optical networks to help to ensure proper operation of the optical networks.

The subject matter claimed herein is not limited to embodiments that solve any disadvantages or that operate only in environments such as those described above. Rather, this background is only provided to illustrate one example technology area where some embodiments described herein may be practiced.

### SUMMARY

According to an aspect of an embodiment, an optical device monitoring system may include a detection unit and a decision unit. The detection unit may be configured to detect a current through an optical device or to detect a voltage across the optical device. The decision unit may be configured to receive the detected current or the detected voltage and to compare the detected current or the detected voltage with normal operating electrical characteristics of the optical device. The decision unit may be further configured to determine optical function failure of the optical device based on the comparison between the detected current or the detected voltage and the normal operating electrical characteristics of the optical device.

The object and advantages of the embodiments will be realized and achieved at least by the elements, features, and combinations particularly pointed out in the claims.

It is to be understood that both the foregoing general description and the following detailed description are exemplary and explanatory and are not restrictive of the invention, as claimed.

### BRIEF DESCRIPTION OF THE DRAWINGS

Example embodiments will be described and explained with additional specificity and detail through the use of the accompanying drawings in which:

FIG. 1 illustrates an example optical device monitoring system;

FIG. 2 illustrates another example optical device monitoring system;

FIG. 3 illustrates another example optical device monitoring system;

FIG. 4 is a flowchart of an example method of determining optical function failure of an optical device; and

FIG. 5 illustrates an optical network that includes an optical device monitoring system.

### DESCRIPTION OF EMBODIMENTS

According to an aspect of an embodiment, an optical device monitoring system is disclosed that is configured to detect electrical characteristics of optical devices. Based on the detected electrical characteristics, the optical device monitoring system may be configured to determine optical function failures of the optical devices.

In some embodiments, the optical device monitoring system may detect electrical characteristics of an optical device, including a voltage across the optical device and a current through the optical device. Based on the detected voltage or the detected current, the optical device monitoring system may be configured to determine normal operating electrical characteristics of the optical device using a table or a diode configured as an electrical model of the optical device. The optical device monitoring system may compare the detected voltage or the detected current to the determined normal operating electrical characteristics. Based on the comparison, the optical device monitoring system may determine optical function failure of the optical device.

Using the electrical characteristics of the optical device to determine an optical function failure may be easier and/or more cost effective than previous methods of determining an optical function failure. Alternately or additionally, determining an optical function failure using the electrical characteristics of the optical device may be performed while an optical network that includes the optical device is operating normally. Previously, an optical function failure of an optical device in an optical network was not able to be determined during normal operation of the optical network. In previous optical networks, optical function failure of an optical device in an optical network was detected during calibration of the optical network based on failures in the optical communications supported by the optical device.

Embodiments of the present invention will be explained with reference to the accompanying drawings.

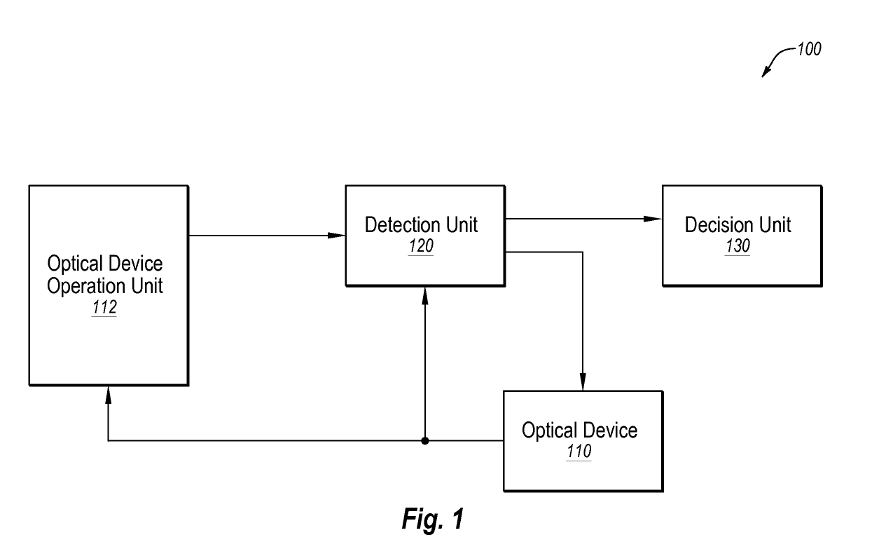

FIG. 1 illustrates an example optical device monitoring system 100 (referred to hereinafter as “system 100”), arranged in accordance with at least one embodiment described herein. The system 100 includes an optical device 110, an optical device operation unit 112, a detection unit 120, and a decision unit 130. In general, the system 100 may be configured to determine optical function failures of the optical device 110.

The optical device 110 may be any device that creates, manipulates, or measures electromagnetic radiation by using or generating electricity. For example, the optical device 110 may include a photo diode configured to measure received electromagnetic radiation by generating a current representing the electromagnetic radiation received by the photodiode. Alternately or additionally, the optical device 110 may include a modulator configured to manipulate electromagnetic radiation based on a current and/or voltage received by the modulator. Alternately or additionally, the optical device 110 may include an optical transmitter configured to generate electromagnetic radiation based on a current and/or voltage received by the optical transmitter. In some embodiments, the optical device 110 may be implemented on a silicon die.

The optical device operation unit 112 may be configured to provide voltage and/or current to the optical device 110 to allow the optical device 110 to create, manipulate, or measure electromagnetic radiation. Alternately or additionally, the optical device operation unit 112 may be configured to receive and to measure voltage and/or current generated by the optical device 110 when the optical device 110 is creating, manipulating, or measuring electromagnetic radiation.

During normal operation of the optical device 110, the optical device 110 may create, manipulate, or measure electromagnetic radiation by using or generating electricity as described. In some circumstances, the optical device 110 may fail to create, manipulate, or measure electromagnetic radiation properly. When the optical device 110 fails to create, manipulate, or measure electromagnetic radiation properly, it may be referred to herein as the optical device 110 experiencing an optical function failure. An optical function failure of the optical device 110 may be a result of overheating, improper manufacture, improper stressing, experiencing excessive voltage, or experiencing excessive current, among other reasons.

When the optical device 110 experiences an optical device failure, the electrical characteristics of the optical device 110 may change from normal operating electrical characteristics of the optical device 110. The system 100 may be configured to detect the electrical characteristics of the optical device 110, e.g., the voltage across the optical device 110 and/or the current through the optical device 110 and to compare the detected electrical characteristics to the normal operating characteristics of the optical device 110 to determine optical device failure of the optical device 110.

The detection unit 120 may be configured to detect the electrical characteristics of the optical device 110. In some embodiments, the detection unit 120 may be configured to detect a voltage across the optical device 110. Alternately or additionally, the detection unit 120 may be configured to detect a current passing through the optical device 110. For example, the optical device 110 may include a photodiode. In these and other embodiments, the detection unit 120 may be configured to detect a voltage between two terminals of the photodiode. The detection unit 120 may also be configured to detect a current flowing between the two terminals of the photodiode. The detection unit 120 may provide the detected voltage and/or current to the decision unit 130.

The decision unit 130 may receive the detected voltage and/or current from the detection unit 120. The decision unit 130 may determine an operating condition of the optical device 110, e.g., whether the optical device 110 is optically functioning properly, or whether the optical device 110 is experiencing an optical function failure based on the received detected voltage and/or current. In particular, the decision unit 130 may be configured to determine an operating condition of the optical device 110 by comparing normal operating characteristics of the optical device 110 with the detected voltage and/or current from the detection unit 120.

In some embodiments, the decision unit 130 may determine the operating condition of the optical device 110 based on a difference between the normal operating characteristics of the optical device 110 and the detected voltage and/or current. In some embodiments, the decision unit 130 may determine that the optical device 110 is experiencing an optical device failure when the difference between the normal operating characteristics of the optical device 110 and the detected voltage and/or current is above a threshold. The threshold may be based on a characterization of the optical device 110. For example, the voltage and/or current associated with the optical device 110 may be recorded under normal operating conditions. Additionally, the voltage and/or current associated with the optical device 110 when the optical device 110 is experiencing an optical device failure may be recorded. The threshold may be based on the amount of difference between the voltage and/or current under normal operating conditions and the voltage and/or current when the optical device 110 is experiencing an optical device failure.

For example, assume that under normal operating conditions the current passing through the optical device 110 ranges between 80 and 100 milliamps (mA) and under optical device failure conditions that current passing through the optical device 110 ranges between 30 and 50 mA. In this example, the normal operating electrical characteristics for current passing through the optical device 110 may be set at 90 mA. The threshold may be set at 30 mA. Thus, if the detected current of the optical device 110 is at or below 60 mA, and thus within the range of optical failure conditions, the difference between the detected current and the normal operating current is 30 mA or more. Thus, the decision unit 130 may determine that the optical device 110 is experiencing an optical function failure. Alternately, if the detected current of the optical device 110 is above 60 mA, and thus within the range of normal operating conditions, the difference between the detected current and the normal operating current is less than 30 mA. Thus, the decision unit 130 may determine that the optical device 110 is optically functioning properly.

In some embodiments, the decision unit 130 may be configured to determine the normal operating characteristics of the optical device 110 based on the detected voltage or the detected current. For example, the detected current may be used to determine the normal operating voltage of the optical device 110 given the detected current. In these and other embodiments, the decision unit 130 may compare the determined normal operating voltage of the optical device 110 to the detected voltage to determine an operating condition of the optical device 110. When the determined normal operating voltage is different from the detected voltage, or more specifically when the magnitude of the difference is greater than the threshold, the optical device 110 may be experiencing an optical function failure.

Alternately or additionally, the detected voltage may be used to determine the normal operating current of the optical device 110 given the detected voltage. In these and other embodiments, the decision unit 130 may compare the determined normal operating current of the optical device 110 to the detected current to determine an operating condition of the optical device 110. When the determined normal operating current is different from the detected current, or more specifically when the magnitude of the difference is greater than the threshold, the optical device 110 may be experiencing an optical function failure.

An example follows of determining the operating condition of the optical device 110. Assume the detected voltage is 1.8 volts (v) and the detected current is 80 mA. The decision unit 130 may determine the normal operating characteristics of the optical device by applying the detected voltage to a diode that is configured as an electrical model of the optical device 110. The diode may output a current based on the detected voltage applied thereto. Because the diode is an electrical model of the optical device 110, the current output by the diode may be included in the normal operating electrical characteristics, e.g., as the normal operating current, of the optical device 110 when the detected voltage is applied to the optical device 110. For example, when a voltage of 1.8 v is applied to the optical device 110 under normal operating conditions, the current passing through the optical device 110 may be 50 mA. In these and other embodiments, the current determined from the diode, e.g., 50 mA, may be compared to the detected current, e.g., 80 mA, to determine the operating condition of the optical device 110. Because the current determined from the diode is different from the detected current or the difference between the current determined from the diode and the detected current is greater than a threshold, the optical device 110 may be experiencing an optical function failure. In these and other embodiments, the diode being an electrical model of the optical device 110 may indicate that the diode has similar currents and/or voltages as the optical device 110 under similar operating conditions.

Another example follows of determining the operating condition of the optical device 110. The decision unit 130 may determine the normal operating characteristics of the optical device by applying the detected current to a table that includes operating characteristics of the optical device 110. By navigating the table to locate the value of the detected current in the table, the corresponding voltage of the optical device 110 may be determined. The corresponding voltage of the optical device may be a normal operating electrical characteristic, e.g., the normal operating voltage, of the optical device 110 when the detected current is passing through to the optical device 110. In these and other embodiments, the voltage determined from the table may be compared to the detected voltage to determine the operating condition of the optical device 110. In some embodiments, the table may be a look-up table that has lists of corresponding currents and voltages during normal operation of the optical device 110. Alternately or additionally, the table may include one or more formulas into which the detected current or voltage may be applied to determine the other of the detected current or voltage during normal operation of the optical device 110. Modifications, additions, or omissions may be made to the system 100 without departing from the scope of the present disclosure.

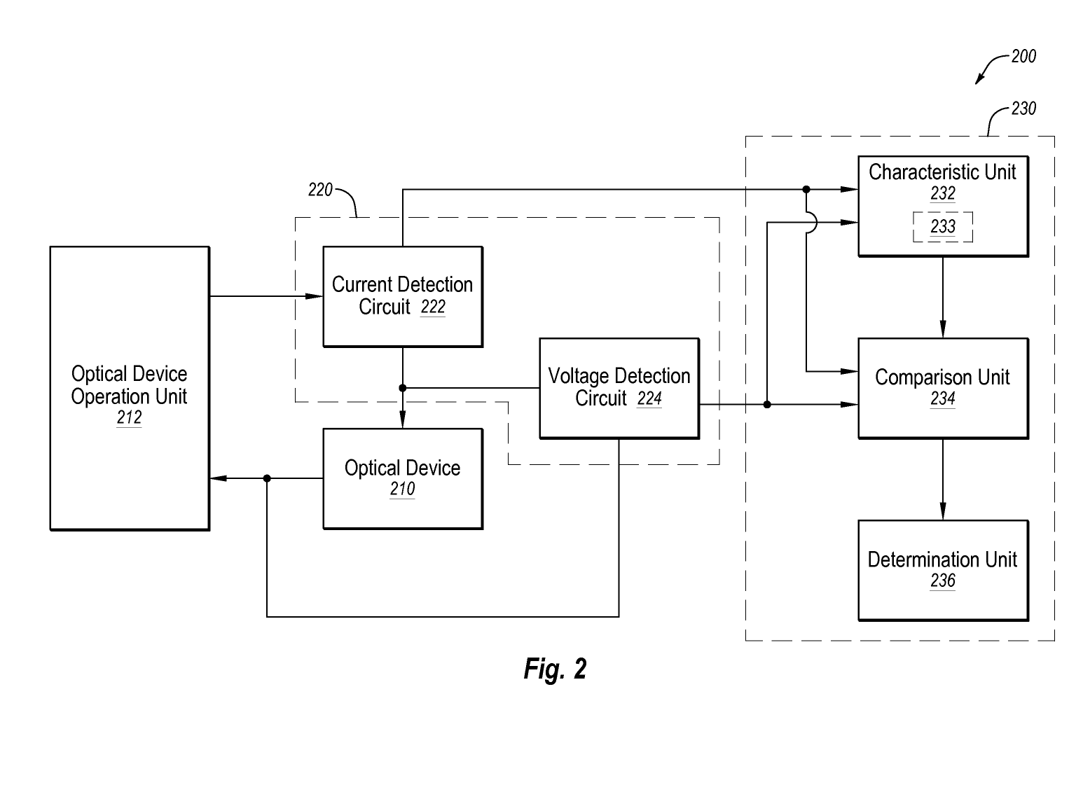

FIG. 2 illustrates another example optical device monitoring system 200 (referred to hereinafter as “system 200”), arranged in accordance with at least one embodiment described herein. The system 200 includes an optical device 210, an optical device operation unit 212, a detection unit 220, and a decision unit 230. In general, the system 200 may be configured to determine optical function failures of the optical device 210.

The optical device 210 and the optical device operation unit 212 may be analogous to the optical device 110 and the optical device operation unit 112 of FIG. 1. The detection unit 220 may include a current detection circuit 222 and a voltage detection circuit 224. The decision unit 230 may include a characteristic unit 232, a comparison unit 234, and a determination unit 236.

The detection unit 220 may be configured to detect the electrical characteristics of the optical device 210. In particular, the current detection circuit 222 may be configured to detect current passing through the optical device 210. In some embodiments, such as the illustrated embodiment, the current detection circuit 222 may have an element in series with the optical device 210 to detect the current. The current detection circuit 222 may be configured to send the detected current to the characteristic unit 232 and to the comparison unit 234.

The voltage detection circuit 224 may be configured to detect a voltage across the optical device 210. The current detection circuit 222 may be configured to send the detected voltage to the characteristic unit 232 and to the comparison unit 234.

The characteristic unit 232 may be configured to determine normal operating electrical characteristics of the optical device 210 based on the detected voltage or the detected current. In some embodiments, the characteristic unit 232 may determine the normal operating electrical characteristics using the detected voltage. In these and other embodiments, the normal operating electrical characteristics may include a normal operating current of the optical device 210 based on the detected voltage. Alternately or additionally, the characteristic unit 232 may determine the normal operating electrical characteristics using the detected current. In these and other embodiments, the normal operating electrical characteristics may include a normal operating voltage of the optical device based on the detected current.

In some embodiments, the characteristic unit 232 may determine the normal electrical operating characteristics based on a table 233 that includes electrical operating characteristics of the optical device 210. Alternately or additionally, the characteristic unit 232 may determine the normal electrical operating characteristics using an physical electrical model of the optical device 210, such as a diode, or some other electrical component. The characteristic unit 232 may send the determined normal electrical operating characteristics to the comparison unit 234.

The comparison unit 234 may be configured to compare the detected voltage or detected current with the determined normal electrical operating characteristics. For example, when the determined normal electrical operating characteristics are based on the detected voltage and include a determined normal current, the comparison unit 234 may compare the detected current to the determined normal current. When the determined normal electrical operating characteristics are based on the detected current and include a determined normal voltage, the comparison unit 234 may compare the detected voltage to the determined normal voltage.

In some embodiments, when comparing the detected voltage or detected current with the determined normal electrical operating characteristics, the comparison unit 234 may be configured to determine a difference between the detected voltage or detected current and the determined normal electrical operating characteristics. The comparison unit 234 may send the results of the comparison to the determination unit 236. In some embodiments, the results of the comparison may include an indication of the difference between the detected voltage or detected current and the determined normal electrical operating characteristics. Alternately or additionally, the results of the comparison may include an indication if a difference exists between the detected voltage or detected current and the determined normal electrical operating characteristics.

The determination unit 236 may be configured to receive the results of the comparison from the comparison unit 234. The determination unit 236 may also be configured to determine if the optical device 210 is experiencing an optical function failure. In some embodiments, the determination unit 236 may determine that the optical device 210 is experiencing an optical function failure when the results of the comparison indicate that there is a difference between the detected voltage or detected current and the determined normal electrical operating characteristics. Alternately or additionally, the determination unit 236 may determine that the optical device 210 is experiencing an optical function failure when the results of the comparison indicate that a difference between the detected voltage or detected current and the determined normal electrical operating characteristics is larger than a threshold difference that indicates an optical function failure of the optical device 210.

Modifications, additions, or omissions may be made to the system 200 without departing from the scope of the present disclosure. For example, in some embodiments, the decision unit 230 and the detection unit 220 may be implemented using analog circuitry. Alternately or additionally, the decision unit 230 may be implemented using digital circuitry and the detection unit 220 may be implemented using analog circuitry. In these and other embodiments, the decision unit 230 may be implemented using hardware that is configured to execute operations to cause the decision unit 230 to operate as described herein. In these and other embodiments, the hardware may execute operations by executing instructions stored in memory. Alternately or additionally, the hardware may include an application-specific integrated circuit (ASIC) or a field-programmable gate array (FPGA) that is configured to execute operations to cause the decision unit 230 to perform the operations described herein. Alternately or additionally, the hardware may execute the operations using a combination of executions performed by an ASIC/FPGA, other hardware, and executions performed based on instructions stored in memory. In these and other embodiments, the table 233 may be stored in the memory with the instructions. Alternately or additionally, the table 233 may be stored as a look-up table.

The memory may be any computer-readable media as described herein. Such computer-readable media may be any available media that may be accessed by a general purpose, special purpose computer (e.g., a processor), or the hardware described. By way of example, and not limitation, such computer-readable media may include a non-transitory or tangible computer-readable storage media including Random Access Memory (RAM), Read-Only Memory (ROM), Electrically Erasable Programmable Read-Only Memory (EEPROM), Compact Disc Read-Only Memory (CD-ROM) or other optical disk storage, magnetic disk storage or other magnetic storage devices, or any other storage medium which may be used to carry or store desired program code in the form of computer-executable instructions or data structures. Combinations of the above may also be included within the scope of computer-readable media.

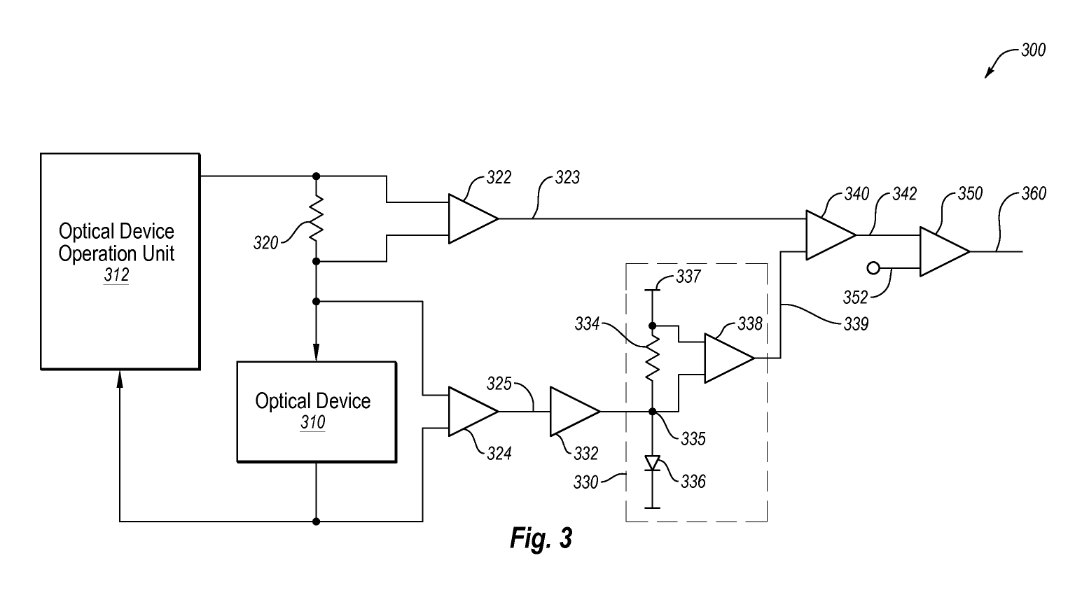

FIG. 3 illustrates another example optical device monitoring system 300 (referred to hereinafter as “system 300”), arranged in accordance with at least one embodiment described herein. The system 300 includes an optical device 310 and an optical device operation unit 312 that may be analogous to the optical devices 110 and 210 and the optical device operation units 112 and 212 of FIGS. 1 and 2, respectively.

The optical device operation unit 312 may send a current to the optical device 310, or the optical device 310 may generate a current and send the current to the optical device operation unit 312. A resistor 320 may be coupled in series between the optical device operation unit 312 and the optical device 310. A voltage may develop across the resistor 320 that is proportional to the current through the optical device 310. The voltage across the resistor 320 may be provided to a current detector differential amplifier 322 (referred to hereinafter as “current detector 322”). The current detector 322 may be configured to output a detected current signal 323. The detected current signal 323 may include a voltage that represents the current through the optical device 310. In some embodiments, the current detector 322 may apply an amplification factor to the detected current signal 323. The amplification factor may be less than one, greater than one, or equal to one. The detected current signal 323 may be sent to a current comparator 340. In some embodiments, the resistor 320 and the current detector 322 may be an example of a current detection circuit, such as the current detection circuit 222 of FIG. 2.

A voltage on both sides of the optical device 310 may be provided to a voltage detector differential amplifier 324 (referred to hereinafter as “voltage detector 324”). The voltage detector 324 may determine a difference between the voltages on both sides of the optical device 310 to thereby determine a voltage across the optical device 310. The voltage detector 324 may output a detected voltage signal 325 based on the difference between the voltages on both sides of the optical device 310. In some embodiments, the voltage detector 324 may apply an amplification factor to the detected voltage signal 325. The amplification factor may be less than one, greater than one, or equal to one. The detected voltage signal 325 may be sent to a characteristic circuit 330. In particular, the detected voltage signal 325 may be sent to a first node 335 in the characteristic circuit 330. In some embodiments, the voltage detector 324 may be an example of a voltage detection circuit, such as the voltage detection circuit 224 of FIG. 2.

In some embodiments, the system 300 may include an equalizing amplifier 332 that may be configured to remove an amplification factor applied to the detected voltage signal 325 by the voltage detector 324. For example, in some embodiments, the equalizing amplifier 332 may be configured with an amplification factor that is the inverse of the amplification factor of the voltage detector 324. As a result, the detected voltage signal 325 may have a similar magnitude as a magnitude of the voltage across the optical device 310 detected by the detected voltage signal 325. The equalizing amplifier 332 may provide the detected voltage signal 325 to the characteristic circuit 330. In some embodiments, when the amplification factor of the voltage detector 324 is one, the system 300 may not include the equalizing amplifier 332.

The characteristic circuit 330 may be configured to generate a signal proportional to or related to a normal operating electrical characteristic of the optical device 310 based on the detected voltage signal 325. The characteristic circuit 330 may include a resistor 334, a model diode 336, and a model current detector 338. The resistor 334 may be coupled between the first node 335 and a voltage source 337. The voltage source 337 may have a magnitude approximately equal or equal to a magnitude of a voltage at a side of the resistor 320 coupled to the optical device operation unit 312. Alternately or additionally, the voltage source 337 may have a voltage of a different magnitude. The model diode 336 may be coupled between the first node 335 and ground. The model current detector 338 may include a differential amplifier and may have a first input coupled to the first node 335 and a second input coupled to the voltage source 337.

The resistor 334 may be configured to be similar to the resistor 320. In some embodiments, the resistor 334 may have a resistance that is approximately equal or equal to a resistance of the resistor 320. The model diode 336 may be configured as an electrical model of the optical device 310. As an electrical model of the optical device 310, the model diode 336 may have similar electrical characteristics of the optical device 310 when the optical device 310 is optically functioning correctly.

The model current detector 338 may be configured to determine a difference between the voltages at the first node 335 and the voltage source 337 and to output a characteristic current signal 339 based on the difference between the voltages at the first node 335 and the voltage source 337. The characteristic current signal 339 may include a voltage that represents the current through the resistor 334 and thus a current through the model diode 336.

In some embodiments, the model current detector 338 may apply an amplification factor to the characteristic current signal 339. The amplification factor may be less than one, greater than one, or equal to one. In some embodiments, the amplification factor applied by the model current detector 338 may be approximately equal or equal to the amplification factor applied by the current detector 322. The characteristic current signal 339 may be sent to the current comparator 340.

A description of an example operation of the characteristic circuit 330 follows. When the detected voltage signal 325 is provided at the first node 335, a current may begin to flow through the model diode 336. Because the model diode 336 is a model of the optical device 310, the current flowing through the model diode 336 may be approximately equal, equal, or proportional to a current that flows though the optical device 310 when a voltage approximately equal, equal, or proportional to the detected voltage signal 325 is applied across the optical device 310. The current flowing through the model diode 336 may also flow through the resistor 334. The model current detector 338 may detect the current flowing through the resistor 334 and may generate the characteristic current signal 339 based on the current flowing through the resistor 334. As a result, the characteristic current signal 339 may represent a normal operating electrical characteristic of the optical device 310 when a voltage approximately equal or equal to the detected voltage signal 325 is applied across the optical device 310.

The current comparator 340 may be configured to compare the characteristic current signal 339 and the detected current signal 323. Based on the comparison between the characteristic current signal 339 and the detected current signal 323, the current comparator 340 may output a current compare signal 342. In some embodiments, the current comparator 340 may include a differential amplifier. In these and other embodiments, the current compare signal 342 may represent a difference between the characteristic current signal 339 and the detected current signal 323. The current compare signal 342 may be provided to a final comparator 350.

The final comparator 350 may be configured to compare the current compare signal 342 with a threshold signal 352. Based on the comparison between the current compare signal 342 and the threshold signal 352, the final comparator 350 may generate a function signal 360. When the current compare signal 342 is less than the threshold signal 352, the function signal 360 may indicate that the optical device 310 is optically functioning correctly. When the current compare signal 342 is more than or equal to the threshold signal 352, the function signal 360 may indicate that the optical device 310 is experiencing an optical function failure.

Modifications, additions, or omissions may be made to the system 300 without departing from the scope of the present disclosure. For example, in some embodiments, the system 300 may not include the final comparator 350. In these and other embodiments, a determination regarding the operation of the optical device 310 may be based on the current compare signal 342. Alternately or additionally, the characteristic circuit 330 and/or the system 300 may include one or more active or passive electrical components.

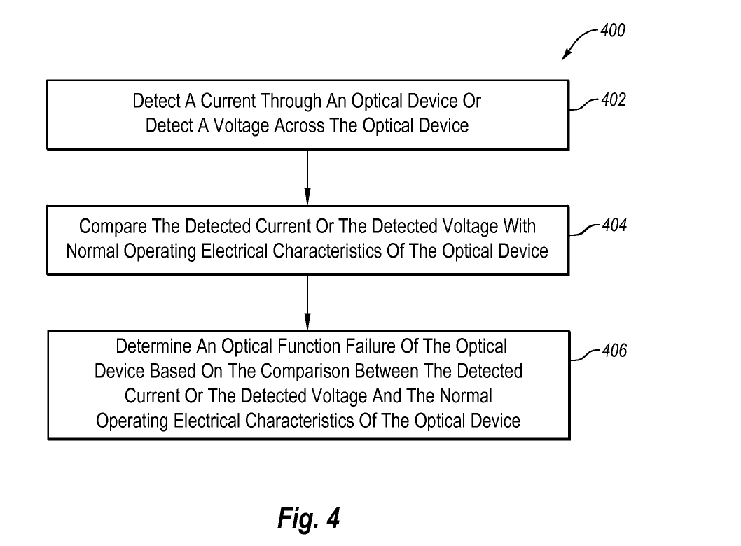

FIG. 4 is a flowchart of an example method 400 of determining optical function failure of an optical device, arranged in accordance with at least one embodiment described herein. The method 400 may be implemented, in some embodiments, by a system, such as the systems 100, 200, or 300 of FIGS. 1, 2, and 3, respectively. Although illustrated as discrete blocks, various blocks may be divided into additional blocks, combined into fewer blocks, or eliminated, depending on the desired implementation.

The method 400 may begin at block 402, where a current through an optical device may be detected or a voltage across the optical device may be detected. In some embodiments, the current through and the voltage across the optical device may both be detected. In block 404, the detected current or the detected voltage may be compared with normal operating electrical characteristics of the optical device.

In block 406, an optical function failure of the optical device may be determined based on the comparison between the detected current or the detected voltage and the normal operating electrical characteristics of the optical device. In some embodiments, the optical device may be determined to have an optical function failure when a difference between the detected current or the detected voltage and the normal operating electrical characteristics of the optical device is greater than a threshold.

One skilled in the art will appreciate that, for this and other processes and methods disclosed herein, the functions performed in the processes and methods may be implemented in differing order. Furthermore, the outlined steps and operations are only provided as examples, and some of the steps and operations may be optional, combined into fewer steps and operations, or expanded into additional steps and operations without detracting from the essence of the disclosed embodiments.

For example, the method 400 may further include detecting the current through an optical device and the voltage across the optical device. In these and other embodiments, the method 400 may further include determining the normal operating electrical characteristics of the optical device based on one of the detected current and the detected voltage. In some embodiments, another of the detected current and the detected voltage may be compared to the determined normal operating electrical characteristics of the optical device. Alternately or additionally, the determining the normal operating electrical characteristics of the optical device may include applying the one of the detected current and the detected voltage to an electrical diode configured as an electrical model of the optical device. Alternately or additionally, the determining the normal operating electrical characteristics of the optical device may include navigating a table that includes operating electrical characteristics of the optical device using the one of the detected current and the detected voltage.

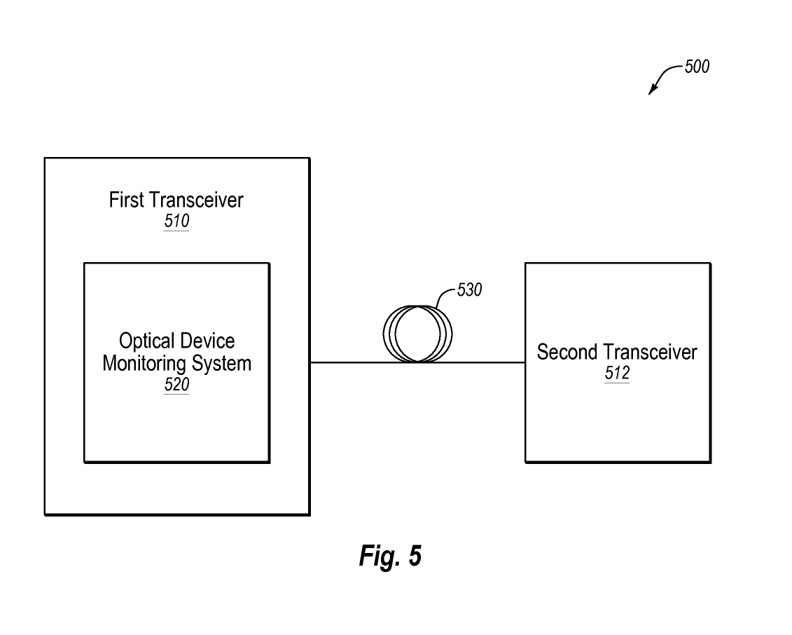

FIG. 5 illustrates an optical network 500 that includes an optical device monitoring system 520, arranged in accordance with at least one embodiment described herein. The optical network 500 includes a first transceiver 510 and a second transceiver 512 that are coupled by an optical cable 530. The first and second transceivers 510 and 512 may be configured to transmit optical signals therebetween along the optical cable 530. The first transceiver 510 may include the optical device monitoring system 520 that is analogous to the systems 100, 200, or 300 of FIGS. 1, 2, and 3. The optical device monitoring system 520 may be configured to determine an operation of an optical device that is included within the first transceiver 510. In particular, the optical device monitoring system 520 may be configured to determine an optical function failure of the optical device in the first transceiver 510. When the optical device experiences an optical function failure, the optical network 500 may compensate for the failure of the optical device such that optical communications may continue undisrupted. Alternately or additionally, when the optical device experiences an optical function failure, the optical network 500 may alert a user of the optical network 500 of the optical function failure so that the optical function failure of the optical device may be remedied.

Modifications, additions, or omissions may be made to the optical network 500 without departing from the scope of the present disclosure. For example, in some embodiments, the second transceiver 512 may also include an optical device monitoring system. Alternately or additionally, the optical network 500 may include additional optical or electrical components than those illustrated.

As used herein, the terms “module,” “component,” or “unit,” may refer to specific hardware implementations configured to perform the operations of the module or component and/or software objects or software routines that may be stored on and/or executed by general purpose hardware (e.g., computer-readable media, processing devices, etc.) of the computing system. In some embodiments, the different components, modules, engines, and services described herein may be implemented as objects or processes that execute on the computing system (e.g., as separate threads). While some of the systems and methods described herein are generally described as being implemented in software (stored on and/or executed by general-purpose hardware), specific hardware implementations or a combination of software and specific hardware implementations are also possible and contemplated. In this description, a “computing entity” may be any computing system as previously defined herein, or any module or combination of modules running on a computing system.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

All examples and conditional language recited herein are intended as pedagogical objects to aid the reader in understanding the invention and the concepts contributed by the inventor to furthering the art, and are to be construed as being without limitation to such specifically recited examples and conditions. Although embodiments of the present inventions have been described in detail, it should be understood that the various changes, substitutions, and alterations could be made hereto without departing from the spirit and scope of the invention.

What is claimed is:

1. An optical device monitoring system comprising:
a detection unit configured to detect a current through an optical device or to detect a voltage across the optical device; and
a decision unit configured to receive the detected current or the detected voltage and to compare the detected current or the detected voltage with normal operating electrical characteristics of the optical device, the decision unit further configured to determine optical function failure of the optical device based on the comparison between the detected current or the detected voltage and the normal operating electrical characteristics of the optical device.

2. The system of claim 1, wherein the decision unit is configured to determine optical function failure of the optical device in response to a difference between the detected current or the detected voltage and the normal operating electrical characteristics of the optical device being greater than a threshold.

3. The system of claim 1, wherein the detection unit comprises a current detection circuit configured to detect the current through the optical device and a voltage detection circuit configured to detect the voltage across the optical device.

4. The system of claim 1, wherein the detection unit is configured to detect the current through the optical device and to detect the voltage across the optical device.

5. The system of claim 4, wherein the decision unit is configured to receive the detected current and the detected voltage, to use one of the detected current and the detected voltage to determine the normal operating electrical characteristics of the optical device, and to compare another of the detected current and the detected voltage to the determined normal operating electrical characteristics of the optical device.

6. The system of claim 5, wherein the decision unit is configured to determine the normal operating electrical characteristics of the optical device using the one of the detected current and the detected voltage and a table that includes operating electrical characteristics of the optical device.

7. The system of claim 5, wherein the decision unit is configured to determine normal operating electrical characteristics of the optical device by using the one of the detected current and the detected voltage and an electrical diode configured as an electrical model of the optical device.

8. The system of claim 1, wherein the optical device is implemented on a silicon die.

9. An optical network that includes an optical transceiver, the optical transceiver including the optical device monitoring system of claim 1.

10. An optical device monitoring system comprising:
a current detection circuit configured to detect a current through an optical device during operation of the optical device;
a voltage detection circuit configured to detect a voltage across an optical device during operation of the optical device;
a characteristic unit configured to determine normal operating electrical characteristics of the optical device based on the detected current or the detected voltage; and
a comparison unit configured to compare the determined normal operating electrical characteristics of the optical device with the detected current or the detected voltage.

11. The system of claim 10, further comprising a determination unit configured to determine optical function failure of the optical device based on the comparison of the determined normal operating electrical characteristics of the optical device and the detected current or the detected voltage.

12. The system of claim 10, wherein the characteristic unit is configured to determine the normal operating electrical characteristics of the optical device using the detected current or the detected voltage and a table that includes operating electrical characteristics of the optical device.

13. The system of claim 10, wherein the characteristic unit is configured to determine the normal operating electrical characteristics of the optical device using the detected current or the detected voltage and an electrical diode configured as an electrical model of the optical device.

14. A method of determining optical function failure of an optical device, the method comprising:
detecting a current through an optical device or detecting a voltage across the optical device;
comparing the detected current or the detected voltage with normal operating electrical characteristics of the optical device; and
determining an optical function failure of the optical device based on the comparison between the detected current or the detected voltage and the normal operating electrical characteristics of the optical device.

15. The method of claim 14, wherein the optical device is determined to have an optical function failure when a difference between the detected current or the detected voltage and the normal operating electrical characteristics of the optical device is greater than a threshold.

16. The method of claim 14, wherein detecting the current through the optical device or detecting the voltage across the optical device comprises both detecting the current through the optical device and detecting the voltage across the optical device.

17. The method of claim 16, further comprising determining the normal operating electrical characteristics of the optical device based on one of the detected current and the detected voltage.

18. The method of claim 17, wherein another of the detected current and the detected voltage is compared to the determined normal operating electrical characteristics of the optical device.

19. The method of claim 17, wherein determining the normal operating electrical characteristics of the optical device includes applying the one of the detected current and the detected voltage to an electrical diode configured as an electrical model of the optical device.

20. The method of claim 17, wherein determining the normal operating electrical characteristics of the optical device includes navigating a table that includes operating electrical characteristics of the optical device using the one of the detected current and the detected voltage.
